(19) United States
(12) Patent Application Publication
(10) Pub. No.: US 2009/0278424 A1
(43) Pub. Date: Nov. 12, 2009

(54) PIEZOELECTRIC TRANSFORMER AND METHOD FOR PRODUCTION THEREOF

(76) Inventors: Heinz Florian, Bad Gams (AT); Alexander Glazunov, Deutschlandsberg (AT); Igor Karfashey, Deutschlandsberg (AT)

Correspondence Address: FISH & RICHARDSON PC, P.O. BOX 1022, MINNEAPOLIS, MN, 55440-1022, US

(21) Appl. No.: 11/720,690

(22) PCT Filed: Nov. 25, 2005
(86) PCT No.: PCT/DE2005/002132

§ 371 Date: Jul. 5, 2007

(30) Foreign Application Priority Data
Dec. 6, 2004 (DE) 102004058743.4

(51) Int. Cl. H01L 41/107; H01L 41/047; H01L 41/22

(52) U.S. Cl. 310/365; 310/367; 29/25.35

(57) ABSTRACT

A piezoelectric transformer includes an input part and an output part. The input part and the output part are mechanically connected along a path that includes an insulating part. The insulating part includes a surface with a depression. In the input part, mechanical oscillations are generated using electrical voltages, and, in the output part, the mechanical oscillations are converted to electrical fields.

### TECHNICAL FIELD

This patent application describes a piezoelectric transformer with a body that contains a piezoelectric material. This patent application also describes a method for producing the transformer.

### BACKGROUND

US 2001/0028206 describes a piezoelectric transformer having internal electrodes inside a body.

### SUMMARY

Described herein is a piezoelectric transformer in which the danger of arcing between different electrical poles is reduced.

In one embodiment, the piezoelectric transformer has a body containing a piezoelectric material. The piezoelectric material can be, for example, a lead zirconate titanate ceramic.

In this application, inverse piezoelectric effect is understood to mean that the piezoelectric ceramic, which may still be polarized for use of the component, undergoes a deformation when an electrical field is applied parallel, perpendicular, or even at an angle to the direction of polarization.

In this application, direct piezoelectric effect is understood to mean that a voltage develops in the body when deformations occur.

According to at least one embodiment, the transformer includes an input part and an output part. In the input part of the transformer, mechanical oscillations in the body of the transformer are generated using electrical voltages. From the output part of the transformer, mechanical oscillations of the body are converted to electrical fields, which can be tapped by electrodes.

Input electrodes can be included in the body. Via the input electrodes, mechanical deformation of the body can be produced when a voltage is applied to the input electrodes.

In another embodiment, output electrodes are included that are in contact with the body. An electrical voltage that develops upon deformation of the body can be tapped via the output electrodes.

The input electrodes and the output electrodes can also be combined with each other within a component. Upon application of alternating voltage to the input electrodes, periodically repeating deformation of the body can be generated. This periodically repeating deformation of the body can give rise to periodically repeating voltage in the output electrodes. Through appropriate arrangement of the electrodes, the output voltage can be different from the input voltage. What is produced is a transformer with a transformer ratio that corresponds to a ratio of the input and output voltages.

An insulating part may be between the input part and the output part. The insulating part electrically isolates the input and output parts from each other. The insulating part may be mechanically connected both to the input part and to the output part.

To reduce the danger of arcing, it is advantageous if a conducting path between the input part and the output part, which runs over a surface of the insulating part, is longer than a direct connection between the input part and the output part. Through this, the insulating capacity of the insulating part can be increased.

Such a lengthening of the conducting path can be achieved, for example, by an appropriate external shaping of the insulating part, for example, by providing an external ripple structure, a concavity or a convexity. All designs of the insulating part which depart from a direct linear surface connection between the input part and the output may be used.

Surface discharges and the resulting arcings can be effectively reduced by lengthening the conducting path on the surface of the transformer.

The insulating/isolating part be provided with a depression on its surface. For example, the depression can have the form of a trench. The trench may be incorporated into the surface of the insulating part, and the input part and the output part of the transformer may be separated by it. The depression can be made by machining a transformer body that has smooth outer surfaces.

According to another embodiment, the transformer includes a depression made in an azimuthal circumferential direction about a long axis of the transformer. Through such a depression design, all possible current paths between the input part and the output part on the surface of the transformer body can be lengthened via the insulating part. It is advantageous if the depression is designed to run completely around a circumference of the transformer body.

In another embodiment of the transformer, depressions are provided in the insulating part on opposite sides of the outer surface of the transformer body. This embodiment is advantageous when the external electrodes of the transformer are also situated on the sides of the transformer body on which the depressions are disposed. The danger of arcing is especially high precisely on the outer surfaces of the transformer on which the external electrodes are situated; as a result, lengthening the current path can be especially effective here.

According to another embodiment of the transformer, the outer surface, or at least a part of the outer surface of the insulating part, is coated with an electrically insulating material. Resistance to arcing between the input part and the output part can be improved through such additional electrical insulation. It is advantageous if the insulating part is designed so that the current path between the input part and the output part is lengthened. In this case, the two effects that increase the insulation strength can be combined with each other.

According to another embodiment of the transformer, the insulating part includes a depression that is partly, or evenly entirely, filled with an insulating material. The filling can project above the depression, i.e., the filling height will be greater than the depth of the depression. In this way, a twofold insulation between the input part and the output part of the transformer can be achieved. For one thing, the distance between the input part and the output part along the surface of the depression is lengthened by comparison with direct connection. For another, the shortest path of connection between the input part and the output part is occupied by an electrically insulating material, so that arcs are still even less likely. This embodiment corresponds to the mechanism of arcing through a volume.

Both organic and inorganic materials may be used as the insulating material. Organic varnishes or organic bonding materials, which typically are good electrical insulators and which are used for passivation of electronic components, may be used as insulating materials.

According to another embodiment of the transformer, edges within the depression or trench and/or edges at the transition between the depression and the outer surface of the body of the element are avoided. This is achieved chiefly through rounding at least one of the edges. The advantage of such rounded edges is that the insulating material applied in the region of the depression or the trench adheres to the surface of the transformer better than when there are sharp edges. The likelihood of separation of the insulating material occurring can be reduced in this way.

In this way, the electric strength of the transformer can be improved.

Moreover, a method for producing a transformer is claimed, where a depression is made in the insulating section of a transformer body between the input part and the output part via a rotating abrasive wheel, such as a grindstone.

An abrasive wheel that has a particular outer contour, with which sharp edges can be prevented in the region of the machined depression, may be used here. The external electrodes of the input and output parts can be generated on the surface of the corresponding transformer part with, for example, a template before or after bonding these transformer parts to the insulating part.

In an advantageous variation of the method, first the input part, the output part and the insulating part are assembled to form a base body. Then, an extensive metal layer is generated on at least two opposite side surfaces of the base body, i.e., on the side surfaces of the input part, the output part and the insulating part. A part of this metal layer is then ground away to produce the depression. Thus, the metal layer is interrupted in the region of the insulating part, and separate external electrodes are formed for the input part and the output part. This variation of the method has the advantage that adjustment of the distance between the external electrodes of the input part and the output part can be managed relatively easily.

Below the transformer and the method for producing it are explained in more detail with reference to examples and the pertinent figures.

### DESCRIPTION OF THE DRAWINGS

FIG. 1 shows an example of a transformer in a perspective view.

FIG. 2A shows a transformer as in FIG. 1 in a schematic cross section, where insulation in the form of a layer is provided.

FIG. 2B shows a transformer as in FIG. 2A, in which the insulation is provided in the form of a fill.

FIG. 3 shows a method for producing a transformer.

FIG. 4 shows an additional embodiment of a transformer in a plate type assembly.

FIG. 5 shows another embodiment of a transformer in the form of a cube.

FIG. 6 shows another embodiment of a transformer in a plate construction with large-area external electrodes in a perspective view.

FIG. 6A shows the transformer as in FIG. 6 in a schematic top view.

In the figures the same reference numbers are used for the same parts or parts with the same or similar function. The drawings are not true to scale, and may include distortions for better representation.

### DETAILED DESCRIPTION

FIG. 1 shows a piezoelectric transformer that includes two parts, a primary part (input part) and a secondary part (output part). The two parts are mechanically bonded together. The input part, output part and insulating part can be bonded together in one piece. For example, this can be managed by stacking ceramic green films with internal electrodes lying between them and then sintering the stack, thus producing a monolithic component element. An electrical signal in the input part is converted to mechanical oscillations of the transformer body via the inverse piezoelectric effect. The mechanical oscillations spread through the body of the transformer and reach the secondary side of the transformer, where they are converted back to an electrical signal via the direct piezoelectric effect. Both the input part and the output part can include several layers of piezoelectric ceramic that are separated from each other by metal electrodes. The ceramic layers in this case may be electrically connected in parallel.

For galvanic separation between the input side and the output side of the transformer, a layer of insulating material is arranged between the two sides. This layer can, for example, include the same piezoelectric material as the other parts of the transformer.

The galvanic separation increases the dielectric strength of the transformer between the input part and the output part.

FIG. 1 shows a transformer with a transformer body 4, which has an input part 1 and an output part 2. The two parts 1 and 2 are connected via an insulating part 3. The input part 1 is provided with electrodes 11 of a first type and with electrodes 12 of a second type. These electrodes 11 and 12 form intermeshing electrode structures, with which electrical fields are generated within the input part 1. The electrodes 11 of the first type are in electrical contact with the external electrode 13. The electrodes 12 of the second type are in contact with the external electrode 14. Similarly, two groups of electrodes 21 and 22 are provided in the output part 2 of the transformer and serve to tap an electrical voltage, where the electrical voltage is produced by the external electrode 23 connected to electrodes 21 or the external electrode 24 connected to electrodes 22. However, the input part and the output part of the transformer can be designed in any other manner.

The insulating part 3 that is arranged between the input part 1 and the output part 2 includes a depression 5 along its entire circumference. Through this depression 5, the current path that runs over the surface, for example, between the edge of the external electrode 13 and the edge of the external electrode 23, can be lengthened relative to direct connection 8 so that the electric strength of the transformer is improved.

The depression 5 can have the shape of a trench, which is machined into the body of the transformer.

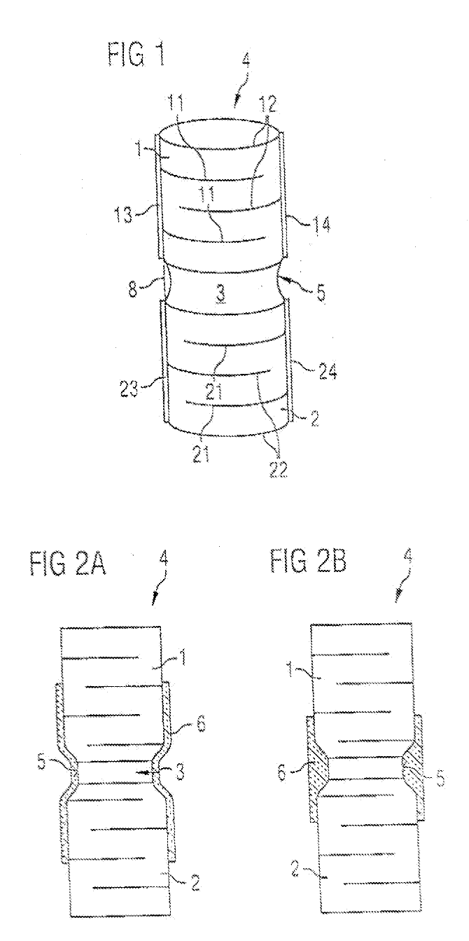

FIG. 2A shows a transformer in cross section, in which a layer that includes insulating material 6 is applied in the region of the insulating part 3. Only the surface of the trench 5 is covered by this layer. Possible causes of surface discharge are dust, moisture or soil on the surface between the electrical poles. The applied insulating layer, among other things, protects the surface of trench 5 against the penetration of dust, moisture or soil during operation of the transformer. In this way the dielectric strength is increased.

FIG. 2B shows a depression that is filled with an insulating material in a manner similar to FIG. 2A. The insulating material 6 projects a little above the depression. The insulation strength can be improved further through this configuration, since now the direct connection, which in FIG. 1 still passes through air, runs through the insulating material 6, so that arcing even along the direct connection becomes still more unlikely.

FIG. 3 shows schematically a possible method for machining the trench 5 into the outer contour of the transformer body. In this case, a rotating abrasive wheel 7 is brought up to the body from outside the body. A depression 5 that is free of edges or in which the edges are rounded can be produced by a suitable outer contour of the abrasive wheel 7, through which the adhesion of the insulating material to the surface of the transformer body can be improved.

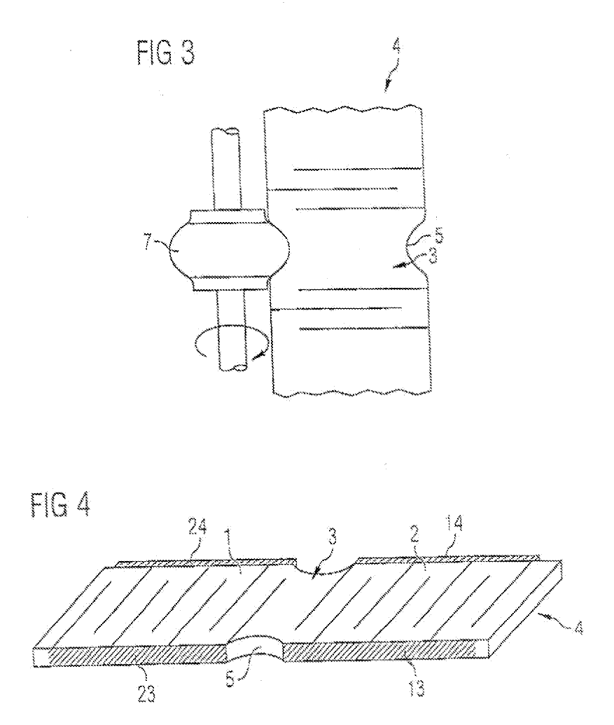

FIG. 4 shows another embodiment of the transformer, which has the shape of a flat plate. The external electrodes are arranged on the narrow sides of the plate. Since now the wide side of the plate is between the external electrodes 13 and 24, or 14 and 23, in this direction there is already a sufficiently long path for discharge between electrodes 14 and 23 or between electrodes 13 and 24. Accordingly, in this case, it is sufficient to provide a depression 5 to lengthen the current path on the narrow side of the plate between the input part and the output part.

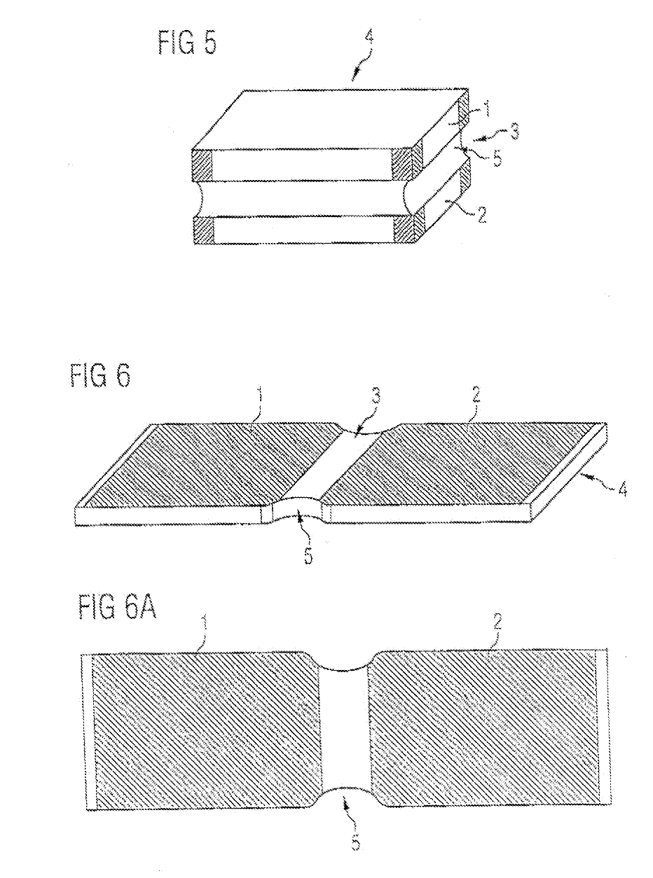

FIGS. 5 and 6 show other embodiments of transformers, in which in each case a depression 5 is provided in the insulating part 3.

The transformer as in FIG. 5 has a number of ceramic layers with internal electrodes arranged in between them. The external electrodes that connect the internal electrodes to each other and that are indicated in the FIG. by hatched areas are arranged at the corners of the square base body.

Another possibility for arranging external electrodes is shown in FIG. 6. The transformer as in FIG. 6 is shown in FIG. 6A in a schematic top view.

The external electrodes, which are indicated by hatching, cover one surface of the base body over a large area. The transformer in this case may include a single ceramic layer, on the opposite large surfaces of which metal layers that serve as external electrodes are applied.

The electrode surfaces extend over the rounded edges of the depression 5. The advantage of depression 5 with such an arrangement of electrodes is that the otherwise sharp edges of the external electrodes are rounded, which provides a reduction of the electrical field strength at the electrode edges. Discharging between two rounded contacts with different poles takes place at a higher electrical voltage than between two contacts that have points. Consequently, a discharge between point electrode edges at the surface of the transformer is prevented by the rounding of the edges of the external electrodes and with that the probability of such a discharge is reduced.

The claims are not limited to the examples described herein, the shape or the number of schematically represented elements that are shown in the figures.

What is claimed is:

1. A piezoelectric transformer comprising:
an input part; and
an output part;
wherein the input part and the output part are mechanically connected along a path that includes an insulating part, the insulating part comprising a surface with a depression.

2. The transformer of claim 1, wherein the surface of the insulating part is around a lengthwise axis of the transformer, and wherein the depression is around a circumference of the insulating part.

3. The transformer of claim 1, wherein the depression comprises one of plural depressions that are on substantially opposite sides of the transformer.

4. The transformer of claim 1, further comprising:
an electrically insulating material on the surface of the insulating part.

5. The transformer of claim 1, further comprising:
an electrically insulating material in the depression.

6. The transformer of claim 4, wherein at least regions of the input part and the output part that are adjacent to the insulating part are coated with the electrically insulating material.

7. The transformer of claim 4, wherein the electrically insulating material comprises an organic material.

8. The transformer of claim 1, wherein the depression comprises edges that are rounded.

9. The transformer of claim 1, further comprising:
metal on surfaces of the input part and the output part, the metal comprising edges that are turned toward each other and that are rounded.

10. A method for producing a transformer, comprising:
forming a depression in an insulating part of the transformer using a rotating abrasive wheel, wherein the insulating part electrically isolates an input part of the transformer from an output part of the transformer.

11. The method of claim 10, wherein forming the depression comprises forming a depression with rounded edges; and
wherein the rotating abrasive wheel comprises an abrasive wheel having an outer surface configured to produce the depression with rounded edges.

12. The method claim 10, further comprising:
assembling the input part, the output part, and the insulating part to form a base body;
forming a metal layer on at least two different side surfaces of the base body; and
grinding the metal layer to remove a part of the metal layer to produce the depression on the insulating part, the depression forming a gap in the metal layer to produce separate external electrodes for the input part and the output part.

13. The method of claim 13, wherein the depression is formed around a circumference of the insulating part.

14. The method of claim 13, wherein the metal layer is formed on substantially opposite sides of the base body.

15. The method of claim 11, further comprising:
assembling the input part, the output part, and the insulating part to form a base body;
forming a metal layer on at least two different side surfaces of the base body; and
grinding the metal layer to remove a part of the metal layer to produce the depression on the insulating part, the depression forming a gap in the metal layer to produce separate external electrodes for the input part and the output part.

16. The method of claim 15, wherein the depression is formed around a circumference of the insulating part.

17. The method of claim 15, wherein the metal layer is formed on substantially opposite sides of the base body.

18. The transformer of claim 1, wherein each of the input part and the output part comprises two or more ceramic layers and electrode layers among the two or more ceramic layers.

19. The transformer of claim 4, wherein the electrically insulating material comprises an inorganic material.

20. The transformer of claim 1, wherein, in the input part, mechanical oscillations are generated using electrical voltages; and
wherein, in the output part, the mechanical oscillations are converted to electrical fields.
